(19) United States
(12) Patent Application Publication
(10) Pub. No.: US 2026/0105224 A1
(43) Pub. Date: Apr. 16, 2026

(54) METHOD AND SYSTEM FOR DEEPWATER BLOWOUT ACCIDENT EMERGENCY DRILL EVALUATION BASED ON VIRTUAL REALITY

(71) Applicant: Beijing Institute of Technology, Beijing (CN)

(72) Inventors: Huixing MENG, Beijing (CN); Jiali LIANG, Beijing (CN); Cheng WANG, Beijing (CN)

(73) Assignee: Beijing Institute of Technology, Beijing (CN)

(21) Appl. No.: 19/062,207

(22) Filed: Feb. 25, 2025

(30) Foreign Application Priority Data
Oct. 12, 2024 (CN) 2024114193200

(51) Int. Cl. G06F 30/28; G06F 3/0362; G06T 15/08; G06T 17/00; G09B 9/00

(52) U.S. Cl. CPC G06F 30/28; G06F 3/0362; G06T 15/08; G06T 17/00; G09B 9/00; G06T 2210/21

(57) ABSTRACT

The present invention discloses a method and system for deepwater blowout accident emergency drill evaluation based on virtual reality, and relates to the technical field of offshore deepwater drilling simulation. The method includes: performing three-dimensional modeling on a deepwater blowout accident scene in a virtual reality environment; constructing a virtual scene based on an established three-dimensional model of the deepwater blowout accident scene; performing result determination according to a simulation operation after constructing the virtual scene, and collecting and exporting operation information; and performing qualitative and quantitative evaluation on a simulation operational status, and performing deepwater blowout accident risk evaluation. The present invention can perform emergency drills for deepwater blowout accidents, and data collection is beneficial to the qualitative and quantitative evaluation on the operation and the risk of the deepwater blowout accidents.

### CROSS-REFERENCE TO RELATED APPLICATIONS

The application claims priority to Chinese patent application No. 2024114193200, filed on Oct. 12, 2024, the entire contents of which are incorporated herein by reference.

### TECHNICAL FIELD

The present invention relates to the technical field of offshore deepwater drilling simulation, and in particular, to a method and system for deepwater blowout accident emergency drill evaluation based on virtual reality.

### BACKGROUND

As one of the most serious accidents in deepwater oil and gas exploration and development activities, blowout is prone to generate significant casualties and property losses. However, traditional offshore drilling safety trainings are mostly carried out in writing and on-site teaching, therefore it is difficult to carry out actual drills. Virtual reality (VR) technology can simulate real accident scenarios, providing a strong sense of immersion, and is widely used in the field of safety training.

Most of the existing VR-based safety training systems mainly carry out simple emergency drills, but are difficult to collect operation data. Evaluation of an operational status is often simply based on whether a final result is successful or not, or manual observation of an operation process, which lacks quantitative evaluation and is difficult to carry out targeted training. Besides, due to difficulties in obtaining data, data-driven deepwater blowout accident risk evaluation is difficult to be carried out.

Therefore, it is urgent to provide a method and system for deepwater blowout accident emergency drill evaluation based on virtual reality.

### SUMMARY

In view of this, the present invention provides a method and system for deepwater blowout accident emergency drill evaluation based on virtual reality, which can perform emergency drills for deepwater blowout accidents, where collection and processing of data are beneficial to the qualitative and quantitative evaluation on the operation and the risk of the deepwater blowout accidents.

To achieve the above objective, the present invention adopts the following technical solutions:

A method for deepwater blowout accident emergency drill evaluation based on virtual reality, including:
performing three-dimensional modeling on a deepwater blowout accident scene in a virtual reality environment;
constructing a virtual scene based on an established three-dimensional model of the deepwater blowout accident scene;
performing result determination according to a simulation operation after constructing the virtual scene, and collecting and exporting operation information; and
performing qualitative and quantitative evaluation on a simulation operational status according to the operation information, and performing deepwater blowout accident risk evaluation.

Preferably, the performing three-dimensional modeling on a deepwater blowout accident scene includes modeling of a blowout accident scene, modeling of a proper operation process of installing an oil collection cap, and modeling of an offshore operating platform.

Preferably, the constructing a virtual scene based on an established three-dimensional model of the deepwater blowout accident scene specifically includes:
rendering the blowout accident scene, the proper operation process of installing the oil collection cap, and the offshore operation platform;
adding operation tips for installing the oil collection cap; and
setting corresponding collision spaces for a lowering operation, an installation abutting operation, and a cutting operation for installing the oil collection cap.

Preferably, the adding operation tips for installing the oil collection cap includes:
prompting an operator of a basic operation method for a VR device when starting to use the device;
prompting operation steps when starting a deepwater blowout accident emergency drill, and setting a confirmation key after each operation is successful; and
prompting whether to exit or continue when an operation fails.

Preferably, the setting corresponding collision spaces for a lowering operation, an installation abutting operation, and a cutting operation for installing the oil collection cap includes:
for the lowering operation: setting a pull-down angle of a remote-control lever of a virtual manipulator to a corresponding lowering accelerated speed, and setting an acceleration time threshold T to limit a lowering speed, wherein a collision space with a volume of R1 is set at a bottom end of a lowered object through a component of a Unity 3D collider;
for the installation abutting operation: respectively adding collision spaces with volumes of V1 and V2 to abutting ends of two to-be-abutted objects through the component of the Unity 3D collider; and
for the cutting operation: respectively adding collision spaces with volumes of V3 and V4 at a cutting position of a to-be-cut object and on a cutter of a system through the component of the Unity 3D collider.

Preferably, the collected operation information includes a step name, a step sequence, an operation time, success or failure, and an error cause; and
determination of the success or failure and the error cause specifically includes:
for the lowering operation: before the collision space R1 and a lowering final position realize physical interaction, if an acceleration time does not exceed the time threshold T, the lowering operation is determined to be successful; and if it exceeds the time threshold, the lowering operation is determined to be failed, and the error cause is recorded at the same time: too fast lowering speed;
for the installation abutting operation: when the collision spaces V1 and V2 realize physical interaction, it is determined that the installation operation is successful, otherwise, it is determined that the installation operation fails, and the error cause is recorded at the same time: wrong installation position; and
for the cutting operation: when the collision spaces V3 and V4 realize physical interaction, it is determined that the cutting operation is successful; when the collision spaces V3 and V4 do not realize interaction, the system determines that the cutting operation fails, and the error cause is recorded at the same time: wrong cutting position or operation object.

Preferably, the method further includes processing the success or failure, and outputting an operation result in a digital form, where 0 represents success, 1 represents failure, and 9 represents failure of a previous step, meaning this step was not executed.

A system for deepwater blowout accident emergency drill evaluation based on virtual reality, including:
a three-dimensional modeling module, configured to perform three-dimensional modeling on a deepwater blowout accident scene in a virtual reality environment;
a virtual scene construction module, configured to construct a virtual scene based on an established three-dimensional model of the deepwater blowout accident scene;
a data collection and processing module, configured to perform result determination according to a simulation operation after constructing the virtual scene, and collect and export operation information; and
an evaluation module, configured to perform qualitative and quantitative evaluation on a simulation operational status according to the operation information, and perform deepwater blowout accident risk evaluation.

From the foregoing technical solutions, it can be seen that compared with the prior art, the present invention discloses a method and system for deepwater blowout accident emergency drill evaluation based on virtual reality, having the following advantages:
1) an existing VR system focuses on safety training, but is difficult to quantitatively evaluate an emergency operational status. According to the present invention, the operational status can be qualitatively evaluated and an operation success rate can be quantitatively calculated by identifying important information of an operator in the operation process and determining the operation result, and reading and processing operation data at the same time, so as to make subsequent targeted improvement.
2) an existing deepwater blowout accident risk evaluation method is mostly based on expert knowledge, which is difficult to evaluate quantitatively. Due to the lack of data, it is also difficult to carry out a data-driven risk evaluation method. According to the present invention, data generated by the VR system can be used for subsequent data-driven deepwater blowout accident risk evaluation, so as to prevent and control accident risks.

### BRIEF DESCRIPTION OF THE DRAWINGS

To explain the technical solutions in the embodiments of the present invention or in the prior art more clearly, the following briefly describes the accompanying drawings required for describing the embodiments or the prior art. Apparently, the accompanying drawings in the following description show only some embodiments of the present invention, and a person of ordinary skill in the art may derive other drawings from these accompanying drawings without creative efforts.

FIG. 1 is a flowchart of a method for deepwater blowout accident emergency drill evaluation based on virtual reality according to the present invention; and

FIG. 2 is a schematic diagram of a system for deepwater blowout accident emergency drill evaluation based on virtual reality according to the present invention.

### DETAILED DESCRIPTION OF THE EMBODIMENTS

The technical solutions in the embodiments of the present invention are clearly and completely described below with reference to the accompanying drawings in the embodiments of the present invention. Apparently, the described embodiments are merely some rather than all of the embodiments of the present invention. All other embodiments obtained by those of ordinary skill in the art based on the embodiments of the present invention without creative efforts shall fall within the protection scope of the present invention.

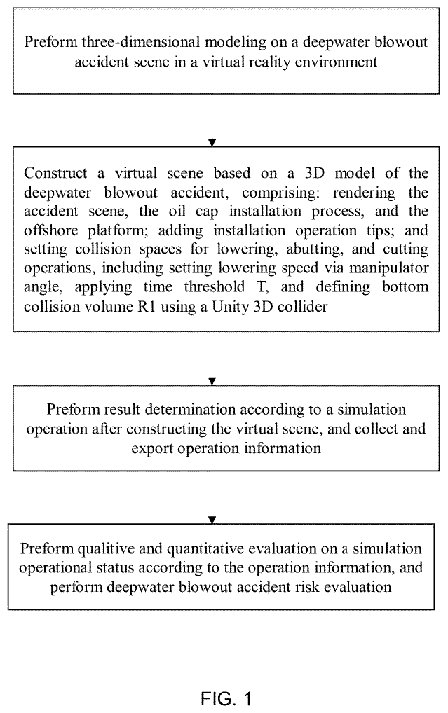

An embodiment of the present invention discloses a method for deepwater blowout accident emergency drill evaluation based on virtual reality, as shown in FIG. 1, including:
performing three-dimensional modeling on a deepwater blowout accident scene in a virtual reality environment through 3DMax, including modeling of a blowout accident scene, modeling of a proper operation process of installing an oil collection cap, and modeling of an offshore operating platform;
constructing a virtual scene based on an established three-dimensional model of the deepwater blowout accident scene;
performing result determination according to a simulation operation after constructing the virtual scene, and collecting and exporting operation information; and
performing qualitative and quantitative evaluation on a simulation operational status according to the operation information, and performing deepwater blowout accident risk evaluation.

In this embodiment, the constructing a virtual scene based on an established three-dimensional model of the deepwater blowout accident scene specifically includes:
rendering the blowout accident scene, the proper operation process of installing the oil collection cap, and the offshore operation platform by using a Unity 3D;
adding operation tips for installing the oil collection cap by using a UI interface in the Unity 3D, including: a basic operation prompt module, configured to prompt an operator of a basic operation method for a VR device when starting to use the device; an emergency operation prompt module, configured to prompt operation steps when starting a deepwater blowout accident emergency drill, and set a “confirmation” key after each operation is successful; and an operation failure prompt module, configured to prompt whether to exit or continue when an operation fails; and
setting corresponding collision spaces for a lowering operation, an installation abutting operation, and a cutting operation for installing the oil collection cap, specifically including:
for the lowering operation: setting a pull-down angle of a remote-control lever of a virtual manipulator to a corresponding lowering accelerated speed, and setting an acceleration time threshold T to limit a lowering speed, wherein a collision space with a volume of R1 is set at a bottom end of a lowered object through a component of a Unity 3D collider, where the lowered object refers to a cutter, a marine riser, an oil collection cap, a drill pipe, or the like;
for the installation abutting operation: respectively adding collision spaces with volumes of V1 and V2 to abutting ends of two to-be-abutted objects through the component of the Unity 3D collider, where the two to-be-abutted objects are the oil collection cap and a drilling wellhead; and
for the cutting operation: respectively adding collision spaces with volumes of V3 and V4 at a cutting position of a to-be-cut object and on a cutter of a system through the component of the Unity 3D collider.

It should be noted that in the event of a blowout accident, installing an oil collection cap can alleviate accident consequences. Steps of installing an oil collection cap include: 1. lowering the oil collection cap; 2. lowering the marine riser and a lower marine riser package (LMRP); 3. lowering the drill pipe and connecting to the oil collection cap; 4. lowering the cutter; 5. cutting an oil leaking pipeline; 6. installing the oil collection cap; 7. tightening the marine riser, the drill pipe, and the oil collection cap.

Referring to the above steps, the present invention is generally divided into three important steps: a lowering operation, an installation abutting operation, and a cutting operation, so it is necessary to set corresponding collision spaces for the lowering operation, the installation abutting operation, and the cutting operation for installing the oil collection cap, so as to determine an operation result.

In this embodiment, at the completion of each step, simulation operation data is collected, including a step name, a step sequence, and an operation time; determining data includes determining success or failure and determining an error cause; and the step name, the step sequence, the operation time, the success or failure, and the error cause are exported. As shown in Table 1, the data collected by simulation for the oil collection cap are as follows:

TABLE 1

| Select a processing | | Operation | Whether an | |
|---|---|---|---|---|
| solution | Step | time (s) | error occurs | Error cause |
| Lowering the oil | 1 | 11.28 | Yes | Speed of lowering the oil |
| collection cap | | | | collection cap is too fast, the |
| | | | | device is out of control, and the |
| | | | | experiment fails |
| Lowering the oil | 2 | 23.56 | Yes | Speed of lowering the oil |
| collection cap | | | | collection cap is too fast, the |
| | | | | device is out of control, and the |
| | | | | experiment fails |
| Lowering the oil | 3 | 77.93 | No | None |
| collection cap | | | | |
| Oil collection cap- | 4 | 16.30 | Yes | Speed of lowering the marine |
| lowering the riser and | | | | riser is too fast, the device is out |
| LMRP | | | | of control, and the experiment |
| | | | | fails |
| Oil collection cap- | 5 | 78.09 | No | None |
| lowering the riser and | | | | |
| LMRP | | | | |
| Oil collection cap- | 6 | 31.70 | No | None |
| lowering the drill pipe and | | | | |
| connecting to the oil | | | | |
| collection cap | | | | |
| Lowering the cutter | 7 | 57.29 | No | None |
| Oil collection cap-cutting | 8 | 1.82 | Yes | Wrong cutting position or |
| the oil leaking pipeline | | | | operation object |
| Oil collection cap-cutting | 9 | 4.26 | No | None |
| the oil leaking pipeline | | | | |
| Installing the oil | 10 | 46.63 | Yes | Wrong installation position |
| collection cap | | | | |
| Installing the oil | 11 | 8.17 | No | None |
| collection cap | | | | |
| Tightening the riser, the | 12 | 6.38 | No | None |
| drill pipe, and the oil | | | | |
| collection cap | | | | |

Determination of the success or failure and the error cause specifically includes:
for the lowering operation: before the collision space R1 and a lowering final position realize physical interaction, if an acceleration time does not exceed the time threshold T, the lowering operation is determined to be successful; and if it exceeds the time threshold, the lowering operation is determined to be failed, and the error cause is recorded at the same time: too fast lowering speed;
for the installation abutting operation: when the collision spaces V1 and V2 realize physical interaction, it is determined that the installation operation is successful, otherwise, it is determined that the installation operation fails, and the error cause is recorded at the same time: wrong installation position; and
for the cutting operation: when the collision spaces V3 and V4 realize physical interaction, it is determined that the cutting operation is successful; when the collision spaces V3 and V4 do not realize interaction, the system determines that the cutting operation fails, and the error cause is recorded at the same time: wrong cutting position or operation object.

The present invention accurately simulates the deepwater blowout accident scene, and provides an immersive accident emergency treatment environment for the operator. The operator is familiar with a blowout accident emergency treatment process through detailed operation guidance. The system provides tips and feedback when the operation is wrong, which improves the training efficiency. In addition, the collected data records information such as results and failure reasons for each step of the operator, which is helpful to improve the emergency operation.

At the completion of each round of operation, the operation results of each step in this round will be collected, and the operation results will be exported after further processing the success or failure, where 0 represents success, 1 represents failure, and 9 represents failure of a previous step, meaning this step was not executed. After processing the data in Table 1, processed data are shown in Table 2:

TABLE 2

| | | Step3_lowering | | | | Step7_tightening |
|---|---|---|---|---|---|---|
| | | the drill pipe | | | | the riser, the |
| Step1_lowering | Step2_lowering | and connecting | | | Step6_installing | drill pipe, and |
| the oil | the riser and | to the oil | Step4_lowering | Step5_cutting | the oil | the oil |
| collection cap | LMRP | collection cap | the cutter | the riser | collection cap | collection cap |
| 1 | 9 | 9 | 9 | 9 | 9 | 9 |
| 1 | 9 | 9 | 9 | 9 | 9 | 9 |
| 0 | 1 | 9 | 9 | 9 | 9 | 9 |
| 0 | 0 | 0 | 0 | 1 | 9 | 9 |
| 0 | 0 | 0 | 0 | 0 | 1 | 9 |
| 0 | 0 | 0 | 0 | 0 | 0 | 0 |

Export and store data: the data in Table 1 and Table 2 will be exported to a computer device connected to an output end through system program codes and stored in a form of table files.

The operation data collected by the present invention are stored in an output device, and the collected data can be used for subsequent data-driven deepwater blowout accident risk evaluation. Traditional accident risk evaluation usually depends on expert experience, but the data-driven evaluation method is difficult to obtain accurate results because of the difficulty in obtaining data. Through the data collection and processing of the VR system, the present invention helps to solve the problem of data deficiencies, can be used for accident risk evaluation, and ensures the safety of emergency operation.

In this embodiment, the performing qualitative and quantitative evaluation on a simulation operational status, and the performing deepwater blowout accident risk evaluation include:

According to the derived Table 1, users can know the operation results and the error causes, so as to make targeted improvements and perform qualitative evaluation on the simulation operational status.

According to the derived Table 2, an operation success rate can be calculated, which is convenient for quantitatively determining the operational status of different users and quantitatively evaluating the simulation operational status; and at the same time, it is helpful to solve the problem of data deficiencies based on a data-driven deepwater blowout accident risk evaluation method.

The present invention can qualitatively and quantitatively evaluate the operational status of an operator. Targeted operation improvements are carried out according to the failure steps and causes. According to the result data table, the operational status is quantitatively evaluated, and at the same time, it serves as data for quantitative evaluation on the risk of deepwater blowout accidents.

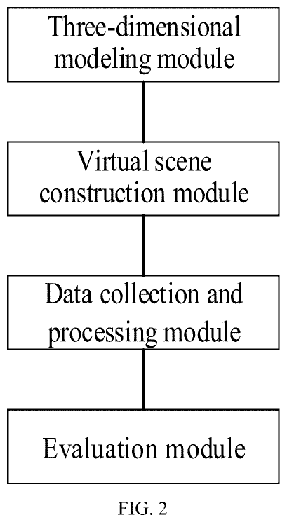

An embodiment of the present invention discloses a system for deepwater blowout accident emergency drill evaluation based on virtual reality, as shown in FIG. 2, including:
a three-dimensional modeling module, configured to perform three-dimensional modeling on a deepwater blowout accident scene in a virtual reality environment, including modeling of a blowout accident scene, modeling of a proper operation process of installing an oil collection cap, and modeling of an offshore operating platform;
a virtual scene construction module, configured to construct a virtual scene based on an established three-dimensional model of the deepwater blowout accident scene;
a data collection and processing module, configured to perform result determination according to a simulation operation after constructing the virtual scene, and collect and export operation information; and
an evaluation module, configured to perform qualitative and quantitative evaluation on a simulation operational status according to the operation information, and perform deepwater blowout accident risk evaluation.

In this embodiment, a specific implementation process of the virtual scene construction module is as follows:
rendering the blowout accident scene, the proper operation process of installing the oil collection cap, and the offshore operation platform by using a Unity 3D;
adding operation tips for installing the oil collection cap by using a UI interface in the Unity 3D, including: a basic operation prompt module, configured to prompt an operator of a basic operation method for a VR device when starting to use the device; an emergency operation prompt module, configured to prompt operation steps when starting a deepwater blowout accident emergency drill, and set a “confirmation” key after each operation is successful; and an operation failure prompt module, configured to prompt whether to exit or continue when an operation fails; and
setting corresponding collision spaces for a lowering operation, an installation abutting operation, and a cutting operation for installing the oil collection cap, specifically including:
for the lowering operation: setting a pull-down angle of a remote-control lever of a virtual manipulator to a corresponding lowering accelerated speed, and setting an acceleration time threshold T to limit a lowering speed, wherein a collision space with a volume of R1 is set at a bottom end of a lowered object through a component of a Unity 3D collider, where the lowered object refers to a cutter, a marine riser, an oil collection cap, a drill pipe, or the like;
for the installation abutting operation: respectively adding collision spaces with volumes of V1 and V2 to abutting ends of two to-be-abutted objects through the component of the Unity 3D collider, where the two to-be-abutted objects are the oil collection cap and a drilling wellhead; and
for the cutting operation: respectively adding collision spaces with volumes of V3 and V4 at a cutting position of a to-be-cut object and on a cutter of a system through the component of the Unity 3D collider.

It should be noted that in the event of a blowout accident, installing an oil collection cap can alleviate accident consequences. Steps of installing an oil collection cap include: 1. lowering the oil collection cap; 2. lowering the marine riser and an LMRP; 3. lowering the drill pipe and connecting to the oil collection cap; 4. lowering the cutter; 5. cutting an oil leaking pipeline; 6. installing the oil collection cap; 7. tightening the marine riser, the drill pipe, and the oil collection cap.

Referring to the above steps, the present invention is generally divided into three important steps: a lowering operation, an installation abutting operation, and a cutting operation, so it is necessary to set corresponding collision spaces for the lowering operation, the installation abutting operation, and the cutting operation for installing the oil collection cap, so as to determine an operation result.

In this embodiment, a specific implementation process of the data collection and processing module is as follows:

At the completion of each step, simulation operation data is collected, including a step name, a step sequence, and an operation time. Determining data includes determining success or failure and determining an error cause; and the step name, the step sequence, the operation time, the success or failure, and the error cause are exported.

Determination of the success or failure and the error cause specifically includes:
for the lowering operation: before the collision space R1 and a virtual seabed realize physical interaction, if an acceleration time does not exceed the time threshold T, the lowering operation is determined to be successful; and if it exceeds the time threshold, the lowering operation is determined to be failed, and the error cause is recorded at the same time: too fast lowering speed;
for the installation abutting operation: when the collision spaces V1 and V2 realize physical interaction, it is determined that the installation operation is successful, otherwise, it is determined that the installation operation fails, and the error cause is recorded at the same time: wrong installation position; and
for the cutting operation: when the collision spaces V3 and V4 realize physical interaction, it is determined that the cutting operation is successful; when the collision spaces V3 and V4 do not realize interaction, the system determines that the cutting operation fails, and the error cause is recorded at the same time: wrong cutting position or operation object.

The present invention accurately simulates the deepwater blowout accident scene, and provides an immersive accident emergency treatment environment for the operator. The operator is familiar with a blowout accident emergency treatment process through detailed operation guidance. The system provides tips and feedback when the operation is wrong, which improves the training efficiency. In addition, the collected data records information such as results and failure reasons for each step of the operator, which is helpful to improve the emergency operation.

At the completion of each round of operation, the operation results of each step in this round will be collected, and the operation results will be exported after further processing the success or failure, where 0 represents success, 1 represents failure, and 9 represents failure of a previous step, meaning this step was not executed.

In this embodiment, the system further includes a data export and storage module. The data in Table 1 and Table 2 will be exported to a computer device connected to an output end through system program codes and stored in a form of table files.

The operation data collected by the present invention can be used for subsequent data-driven deepwater blowout accident risk evaluation. Traditional accident risk evaluation usually depends on expert experience, but the data-driven evaluation method is difficult to obtain accurate results because of the difficulty in obtaining data. Through the data collection of the VR system, the present invention helps to solve the problem of data deficiencies, can be used for accident risk evaluation, and ensures the safety of emergency operation.

In this embodiment, a specific implementation process of the evaluation module is as follows:

According to the derived Table 1, users can know the operation results and the error causes, so as to make targeted improvements and perform qualitative evaluation on the simulation operational status.

According to the derived Table 2, an operation success rate can be calculated, which is convenient for quantitatively determining the operational status of different users and quantitatively evaluating the simulation operational status; and at the same time, it is helpful to solve the problem of data deficiencies based on a data-driven deepwater blowout accident risk evaluation method.

The present invention qualitatively and quantitatively evaluates the operational status of an operator. Targeted operation improvements are carried out according to the failure steps and causes. According to the result data table, the operational status is quantitatively evaluated, and at the same time, it serves as data for quantitative evaluation on the risk of deepwater blowout accidents.

The system of the present invention is developed on the basis of VR technology, and uses virtual modeling, operation guidance, or the like to make the operator be personally on the scene and be familiar with the emergency operation process, so as to improve the effect of emergency training for deepwater blowout accidents.

Various embodiments in the specification are described in a progressive manner, and each embodiment focuses on the differences from the other embodiments, and the same or similar parts between the various embodiments can refer to each other. The apparatus disclosed in the embodiments is described relatively simply because it corresponds to the method disclosed in the embodiments, and for portions related to those of the method, reference may be made to the description of the method.

The above description of the disclosed embodiments enables a person skilled in the art to implement or use the present invention. Various modifications to these embodiments will be readily apparent to a person skilled in the art, and the generic principles defined herein may be implemented in other embodiments without departing from the spirit or scope of the present invention. Therefore, the present invention is not intended to be limited to the embodiments shown herein, but is to be in accordance with the widest scope consistent with the principles and novel features disclosed herein.

What is claimed is:

1. A method for generating objective operator performance data using a virtual reality simulation of a deepwater blowout accident emergency drill, comprising:
performing three-dimensional modeling on a deepwater blowout accident scene in a virtual reality environment, comprising modeling of a blowout accident scene, modeling of a proper operation process of installing an oil collection cap, and modeling of an offshore operating platform;
constructing a virtual scene based on an established three-dimensional model of the deepwater blowout accident scene, specifically comprising:
rendering the blowout accident scene, the proper operation process of installing the oil collection cap, and the offshore operation platform;
adding operation tips for installing the oil collection cap; and
setting corresponding collision spaces for a lowering operation, an installation abutting operation, and a cutting operation for installing the oil collection cap, specifically comprising:
for the lowering operation: setting a pull-down angle of a remote-control lever of a virtual manipulator to a corresponding lowering accelerated speed, and setting an acceleration time threshold T to limit a lowering speed, wherein a collision space with a volume of R1 is set at a bottom end of a lowered object through a component of a collider component of a virtual reality engine;
for the installation abutting operation: respectively adding collision spaces with volumes of V1 and V2 to abutting ends of two to-be-abutted objects through the component of the collider component of the virtual reality engine; and
for the cutting operation: respectively adding collision spaces with volumes of V3 and V4 at a cutting position of a to-be-cut object and on a cutter of a system through the component of the collider component of the virtual reality engine;
performing result determination according to a simulation operation after constructing the virtual scene, and collecting and exporting operation information; and
transforming, by a processor, the collected operation information into a structured data file configured for subsequent data-driven deepwater blowout accident risk evaluation; wherein
the collected operation information comprises a step name, a step sequence, an operation time, success or failure, and an error cause; and
wherein the determination of the success or failure and the error cause is performed by the processor applying a specific set of computer-implemented rules, the rules specifically comprising:
for the lowering operation: before the collision space R1 and a lowering final position realize physical interaction, if an acceleration time does not exceed the time threshold T, the lowering operation is determined to be successful; and if it exceeds the time threshold, the lowering operation is determined to be failed, and the error cause is recorded at the same time: too fast lowering speed;
for the installation abutting operation: when the collision spaces V1 and V2 realize physical interaction, it is determined that the installation operation is successful, otherwise, it is determined that the installation operation fails, and the error cause is recorded at the same time: wrong installation position; and
for the cutting operation: when the collision spaces V3 and V4 realize physical interaction, it is determined that the cutting operation is successful; when the collision spaces V3 and V4 do not realize interaction, the system determines that the cutting operation fails, and the error cause is recorded at the same time: wrong cutting position or operation object;
processing the success or failure, and outputting an operation result in a digital form, comprising success, failure, and failure of a previous step, meaning this step was not executed.

2. The method for generating objective operator performance data using the virtual reality simulation of the deepwater blowout accident emergency drill according to claim 1, wherein the adding operation tips for installing the oil collection cap comprises:
prompting an operator of a basic operation method for a VR device when starting to use the device;
prompting operation steps when starting a deepwater blowout accident emergency drill, and setting a confirmation key after each operation is successful; and
prompting whether to exit or continue when an operation fails.

3. The method for generating objective operator performance data using the virtual reality simulation of the deepwater blowout accident emergency drill according to claim 2, wherein the operation result specifically comprises: 0 represents success, 1 represents failure, and 9 represents failure of a previous step, meaning this step was not executed.

4. A system for generating objective operator performance data using the virtual reality simulation of the deepwater blowout accident emergency drill, wherein the system is realized based on the method according to claim 1, and comprises:
a processor;
a memory that stores instructions executed by the processor;
a three-dimensional modelling module, implemented on the processor, configured to perform three-dimensional modeling on a deepwater blowout accident scene in a virtual reality environment;
a virtual scene construction module, implemented on the processor, configured to construct a virtual scene based on an established three-dimensional model of the deepwater blowout accident scene;
a data collection and processing module, implemented on the processor, configured to perform result determination according to a simulation operation after constructing the virtual scene, and collect and export operation information; and
an evaluation module, implemented on the processor, configured to transform the collected operation information into a structured data file configured for subsequent data-driven deepwater blowout accident risk evaluation.
